(19) United States
(12) Patent Application Publication
(10) Pub. No.: US 2024/0312847 A1
(43) Pub. Date: Sep. 19, 2024

(54) OPTIMIZATION METHOD OF OVERLAY MEASUREMENT DEVICE AND OVERLAY MEASUREMENT DEVICE PERFORMING THE SAME

(71) Applicant: AUROS TECHNOLOGY, INC., Hwaseong-si (KR)

(72) Inventor: Seung Soo LEE, Osan-si (KR)

(21) Appl. No.: 18/296,502

(22) Filed: Apr. 6, 2023

(30) Foreign Application Priority Data
Mar. 15, 2023 (KR) 10-2023-0033915

(51) Int. Cl. H01L 21/66; G03F 7/00; G03F 7/20

(52) U.S. Cl. CPC H01L 22/12; G03F 7/70653; G03F 7/7085; H01L 22/24

(57) ABSTRACT

The present disclosure relates to a method of optimizing an overlay measurement device by adjusting locations and aperture shapes of a plurality of diaphragms provided in an optical path of the overlay measurement device. The method may include measuring initial performance indicators that are performance indicators of the overlay measurement device using an initial parameter combination based on the locations and the aperture shapes of the plurality of diaphragms, with respect to at least one location on a semiconductor wafer on which an overlay mark to be measured is formed; automatically obtaining, on the basis of the initial performance indicators, an optimal parameter combination based on the locations and the aperture shapes of the plurality of diaphragms; and changing the locations and the aperture shapes of the plurality of diaphragms according to the optimal parameter combination.

### CROSS REFERENCE TO RELATED APPLICATION

The present application claims priority to Korean Patent Application No. 10-2023-0033915, filed Mar. 15, 2023, the entire contents of which is incorporated herein for all purposes by this reference.

### BACKGROUND OF THE INVENTION

### Field of the Invention

The present disclosure relates to an optimization method of an overlay measurement device. More particularly, the present disclosure relates to a method of optimizing an overlay measurement device by adjusting locations and aperture shapes of a plurality of diaphragms provided in an optical path of the overlay measurement device.

### Description of the Related Art

A plurality of pattern layers are sequentially formed on a semiconductor substrate. In addition, a circuit of one layer may be formed in two patterns through double patterning. Pattern layers or a plurality of patterns of one layer need to be formed accurately at preset positions so as to manufacture a desired semiconductor device.

In order to verify whether pattern layers are accurately aligned, overlay marks formed simultaneously with the pattern layers are used.

A method of measuring overlay by using an overlay mark is as follows. First, in a pattern layer formed in a previous process, for example, an etching process, one structure that is a part of the overlay mark is formed simultaneously with the formation of the pattern layer. Then, in a subsequent process, for example, a photolithography process, the remaining structure of the overlay mark is formed on the photoresist.

Next, an overlay measurement device acquires (1) an image of the overlay structure (acquires the image with penetration through the photoresist layer) of the pattern layer formed in the previous process and (2) an image of the overlay structure of the photoresist layer, and the overlay measurement device measures an offset value between the centers of the images to measure an overlay error value.

More specifically, JP 2020-112807A discloses a method in which an image of an overlay mark formed on a substrate is captured, a plurality of working zones is selected from the captured image, a signal having information for each of the selected working zones is formed, and the signals are compared to determine relative shift between different layers or different patterns.

FIG. 1 is a plan view of an example of an overlay mark. The overlay mark 1 shown in FIG. 1 includes four sets of working zones 4, 5, 6, and 7. Each of the sets of working zones 4, 5, 6, and 7 includes two working zones positioned in a diagonal line. Each of the sets of working zones 4, 5, 6, and 7 is used for overlay measurement in the direction of the X-axis or Y-axis of the pattern layer that is formed together with the corresponding set of working zones. In order to prevent an interference phenomenon, structures 2 formed with a first pattern layer and structures 3 formed with a second pattern layer are placed so as not to overlap each other.

Each working zone includes bars that are placed at regular intervals starting from the center of the overlay mark 1 to the outer edge of the overlay mark 1. Accordingly, using the overlay measurement device, a periodic signal may be obtained from each of the two working zones belonging to each of the sets of working zones 4, 5, 6, and 7, as shown in FIG. 2. The graph of FIG. 2 may be obtained from a selected partial area 8 shown in FIG. 1, for example.

In the graph of FIG. 2, the peaks are positioned where the bars are placed. Since the bars are periodically placed in the conventional overlay mark 1, the obtained signals also have periodicity. In addition, the overlay is measured through correlation analysis of two periodic signals obtained from two selected areas 8 and 8′.

Before the above-described measurement for determining an overlay error value, optimization of the overlay measurement device is required. That is, it is necessary to optimize performance indicators of the overlay measurement device, for example, the precision, total measurement uncertainty (TMU), tool-induced shift (TIS), move-acquire-measure (MAM) time, etc. of the overlay measurement device.

The total measurement uncertainty depends on a plurality of coefficients, such as precision, a mean of the tool-induced shift, a 3-sigma value of the tool-induced shift, etc. Preferably, the value of the total measurement uncertainty is small.

The tool-induced shift may be quantified by measuring the same feature, for example, an overlay mark, on a semiconductor wafer with respect to 0 and 180 degree rotations of the semiconductor wafer. In this case, the tool-induced shift is equal to half of the sum of overlay error measurement values with respect to 0 and 180 degree rotations. Preferably, the means of X values and Y values of the tool-induced shift measured at a plurality of locations are close to 0 and a 3-sigma value is small.

More specifically, the tool-induced shift may be measured in the following way.

First, with respect to 0 and 180 degree rotations of the semiconductor wafer, a plurality of overlay marks are photographed at many sites on the semiconductor wafer to obtain overlay mark images, and the overlay mark images are analyzed to measure overlay errors in the X direction and the Y direction.

Then, half of the sum of overlay error measurement values with respect to 0 and 180 degree rotations of the same overlay mark is acquired as a tool-induced shift value at the corresponding location. Regarding the tool-induced shift value, an X-direction value and a Y-direction value are obtained for each site.

FIG. 3 is a diagram illustrating measurement sites on a semiconductor wafer that are expressed as dots. FIG. 4 is a diagram illustrating tool-induced shift values, on the XY-plane, obtained from the sites shown in FIG. 3.

As shown in FIG. 4, tool-induced shift values may vary according to site. Preferably, the mean value of the tool-induced shift values is (0, 0) and the 3-sigma value of the tool-induced shift values is a minimum. For example, the specification of the tool-induced shift may be set to the mean value of 0.3 nm less and the 3-sigma value of 0.4 nm or less.

Short move-acquire-measure time suggests a faster frame time.

Until the overlay measurement device is optimized for a particular overlay mark, a worker adjusts various operating parameters. This optimization procedure is repeated for other overlay marks. This optimization procedure is performed by worker, so it is time consuming. In addition, when a plurality of workers optimize overlay measurement devices, the performances of the respective overlay measurement devices may vary.

The foregoing is intended merely to aid in the understanding of the background of the present disclosure, and is not intended to suggest that the present disclosure falls within the purview of the related art that is already known to those skilled in the art.

### Documents of Related Art

(Patent Document 1) Korean Patent No. 10-1329827
(Patent Document 2) Korean Patent Application Publication No. 10-2022-0164003

### SUMMARY OF THE INVENTION

The present disclosure is directed to providing a method of optimizing an overlay measurement device by adjusting at least one of locations and aperture shapes of a plurality of diaphragms placed in an optical path of an overlay measurement device.

According to one or more embodiments of the present disclosure, there is provided a method of optimizing an overlay measurement device by adjusting at least one of locations and aperture shapes of a plurality of diaphragms placed in an optical path of the overlay measurement device, the method including: a) measuring initial performance indicators of the overlay measurement device using an initial parameter combination based on the locations and the aperture shapes of the plurality of diaphragms, with respect to at least one location on a semiconductor wafer on which an overlay mark to be measured is formed; b) automatically obtaining, on the basis of the initial performance indicators, an optimal parameter combination based on the locations and the aperture shapes of the plurality of diaphragms; and c) changing the locations and the aperture shapes of the plurality of diaphragms according to the optimal parameter combination.

In addition, in the step b), the optimal parameter combination may be obtained by inputting the initial performance indicators to a machine learning model configured to output the optimal parameter combination.

In addition, in the step b), the automatically obtaining the optimal parameter combination may include obtaining performance indicators for each of a plurality of parameter combinations based on the locations and the aperture shapes of the plurality of diaphragms for each respective parameter combination; assigning weightings to the performance indicators of each parameter combination, respectively; and selecting the optimal parameter combination by selecting one parameter combination among the plurality of parameter combinations which minimizes a sum of the performance indicators to which the weightings are assigned as the optimal parameter combination.

In addition, the performance indicators may include at least one selected from a group of precision, total measurement uncertainty (TMU), tool-induced shift (TIS), move-acquire-measure (MAM) time, and statistic values of the performance indicators.

In addition, the diaphragms may include at least one field stop and at least one aperture stop.

In addition, the overlay measurement device may be an infinity-corrected optical system, and the at least one aperture stop may be provided in an infinity-corrected section in which light rays travel in parallel.

In addition, the overlay measurement device may further include an illumination source to generate light, an objective lens to receive light and direct light toward the semiconductor wafer and to collect light reflected from the semiconductor wafer, and an image detector to detect the overlay mark formed on the semiconductor wafer from the collected light and to generate an overlay mark image of the overlay mark; and the at least one aperture stop may be placed between the image detector and then objective lens of the overlay measurement device.

In addition, the aperture shapes of the diaphragms may be selected among circular, quadrangular, ring, and cross shapes.

In addition, one or more of the plurality of diaphragms may be a variable diaphragm.

In addition, one or more of the variable diaphragms may be an iris-type variable diaphragm of which an aperture diameter varies.

In addition, one or more of the variable diaphragms may be provided with a plate in which a plurality of apertures having different shapes are formed, and may be configured to change the aperture placed in the optical path by rotating or linearly moving the plate.

In addition, according to one or more embodiments of the present disclosure, there is provided an overlay measurement device, including: an imaging device including a plurality of diaphragms placed in an optical path for obtaining an overlay mark image; and a controller communicatively coupled to the imaging device, the controller including at least one memory comprising instructions and the controller further including at least one processor configured to execute the instructions within the at least one memory to implement: a) measuring initial performance indicators of the overlay measurement device using an initial parameter combination based on locations and aperture shapes of the plurality of diaphragms, with respect to at least one location on a semiconductor wafer on which an overlay mark to be measured is formed; b) automatically obtaining, on the basis of the initial performance indicators, an optimal parameter combination based on the locations and the aperture shapes of the plurality of diaphragms; and c) changing the locations and the aperture shapes of the plurality of diaphragms according to the optimal parameter combination.

The optimization method of the overlay measurement device according to the present disclosure acquires, on the basis of measured initial performance indicators, an optimal parameter combination related to the locations and the aperture shapes of the plurality of diaphragms automatically, so that human intervention can be minimized. Accordingly, the time required for optimization can be reduced. In addition, the performances of respective overlay measurement devices can be kept constant.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a plan view of an example of an overlay mark;

FIG. 2 is a view showing a signal obtained from one working zone of the overlay mark shown in FIG. 1;

FIG. 3 is a diagram illustrating measurement sites on a semiconductor wafer that are expressed as dots;

FIG. 4 is a diagram illustrating tool-induced shift values, on the XY-plane, obtained from the sites shown in FIG. 3;

FIG. 5 is a schematic diagram illustrating an overlay measurement device according to an embodiment of the present disclosure;

FIG. 6 is a diagram illustrating examples of a plate-type variable diaphragm; and

FIG. 7 is a flowchart illustrating an optimization method of an overlay measurement device according to an embodiment of the present disclosure.

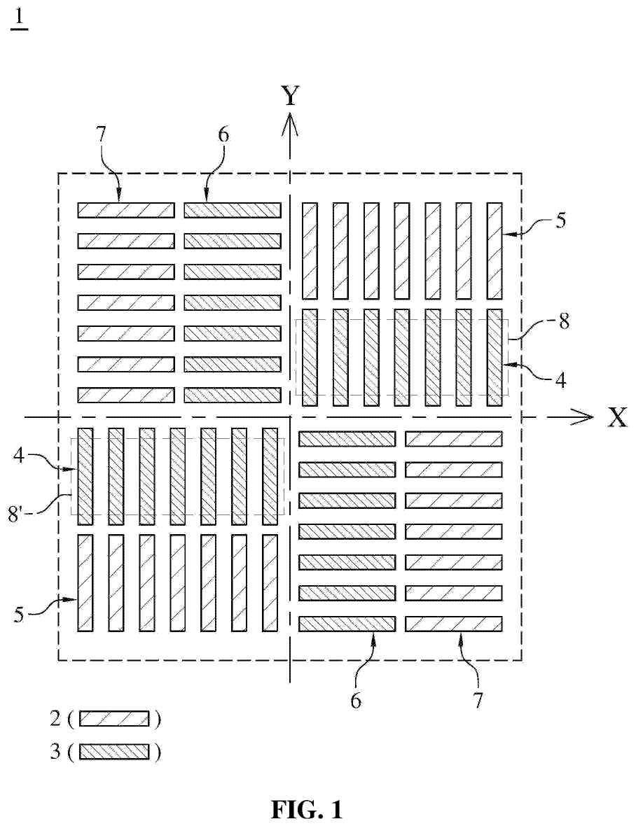

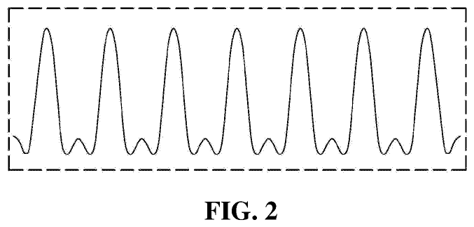

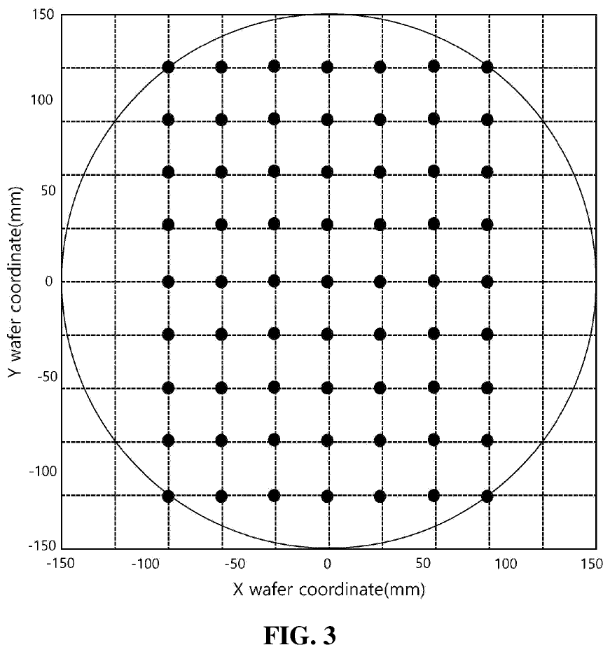

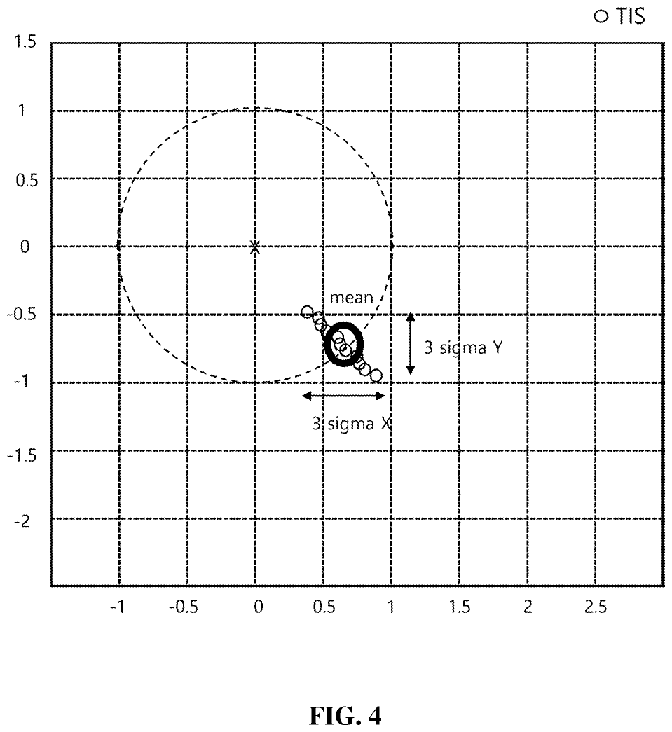

### DETAILED DESCRIPTION OF THE INVENTION

Hereinafter, embodiments of the present disclosure will be described in detail with reference to the accompanying drawings. It should be understood that the embodiments of the present disclosure may be changed to a variety of embodiments and the scope of the present disclosure is not limited to the embodiments described hereinbelow. The embodiments of the present disclosure are provided in order to fully describe the disclosure for those of ordinary skill in the art. Therefore, shapes and sizes of the elements in the drawings may be exaggerated for a more precise description. Throughout the drawings, the elements denoted by the same reference numerals refer to the same elements.

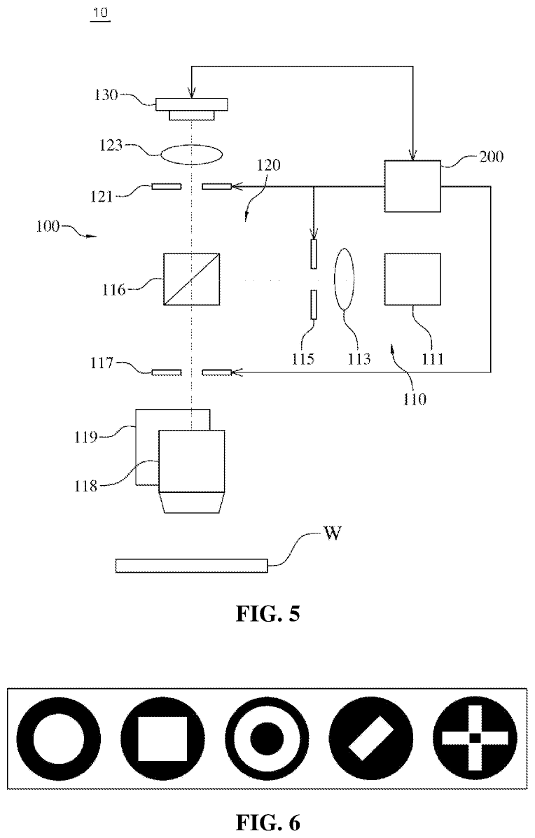

FIG. 5 is a schematic diagram illustrating an overlay measurement device according to an embodiment of the present disclosure.

The overlay measurement device 10 includes: an imaging system 100 for obtaining an overlay mark image; and a controller 200. The overlay measurement device 10 photographs a semiconductor wafer, on which an overlay mark is formed, to obtain an overlay mark image. The obtained overlay mark image is analyzed to measure overlay errors between pattern layers formed on the wafer.

The controller 200 is coupled to the imaging system 100 such that wired or wireless communication is achieved therebetween. The controller 200 includes hardware, such as a one or more processors, one or more memories, etc., and software installed in the one or more memories. Through instructions of the software, the controller 200 may instruct the one or more processors to perform steps of an optimization method of the overlay measurement device 10.

As shown in FIG. 5, the imaging system 100 of the overlay measurement device 10 includes: an illumination optical system 110 for illuminating an overlay mark on a semiconductor wafer W; an image-forming optical system 120 for concentrating the reflected light from the overlay mark to form an overlay mark image; and an image detector 130 for obtaining the overlay mark image formed by the image-forming optical system 120.

The illumination optical system 110 may be configured using various optical elements. For example, the illumination optical system 110 may include an illumination source 111, a first diaphragm 115, a beam splitter 116, a second diaphragm 117, and an objective lens 118. In addition, the illumination optical system 110 may further include a lens 113 placed between the illumination source 111 and the first diaphragm 115.

The illumination source 111 may include a light source for generating light of a wide wavelength band, and variable optical filters for adjusting the wavelength band of the transmitted light.

The first diaphragm 115 is a field stop that adjusts the size and shape of the illumination. A location and an aperture shape of the first diaphragm 115 in the optical path affect the numerical aperture (NA) and the depth of focus (DOF), and thus affect the measurement conditions, such as total measurement uncertainty (TMU), tool-induced shift (TIS), etc., of the overlay measurement device overall. The location of the first diaphragm 115 in the optical path includes a location on a plane orthogonal to an optical axis and a location in a direction orthogonal to the optical axis.

The beam splitter 116 is placed between the illumination source 111 and the objective lens 118, and transfers the illumination from the illumination source 111 to the objective lens 118.

The second diaphragm 117 is an aperture stop that adjusts the amount of light and aberrations of the illumination. A location and an aperture shape of the second diaphragm 117 in the optical path are based on telecentricity that affects the tool-induced shift. Therefore, the tool-induced shift may be minutely controlled by adjusting the location and the aperture shape of the second diaphragm 117 in the optical path. The location of the second diaphragm 117 in the optical path includes a location on a plane orthogonal to the optical axis and a location in a direction orthogonal to the optical axis.

The location and the aperture shape of the first diaphragm 115 in the optical path are adjusted to improve the performance indicators of the overlay measurement device 10 overall as much as possible, and the location and the aperture shape of the second diaphragm 117 in the optical path are adjusted to control the tool-induced shift minutely.

The objective lens 118 concentrates the illumination onto a measurement location on the surface of the semiconductor wafer W, and collects the reflected light reflecting off the measurement location. The objective lens 118 is provided in a lens focus actuator 119. The lens focus actuator 119 is used to adjust the distance between the objective lens 118 and the semiconductor wafer W.

The image-forming optical system 120 may be configured using various optical elements. For example, the image-forming optical system 120 may include a third diaphragm 121 and a tube lens 123. In addition, the image-forming optical system 120 may use the beam splitter 116, the second diaphragm 117, and the objective lens 118 of the illumination optical system 110.

The third diaphragm 121 is an aperture stop that adjusts the amount of light and aberrations of the reflected light. A location and an aperture shape of the third diaphragm 121 in the optical path are related to telecentricity that affects the tool-induced shift. Therefore, the tool-induced shift may be minutely controlled by adjusting the location and the aperture shape of the third diaphragm 121 in the optical path. The location of the third diaphragm 121 in the optical path includes a location on a plane orthogonal to the optical axis and a location in a direction orthogonal to the optical axis.

In an embodiment, the second diaphragm 117 or the third diaphragm 121 may be omitted. The overlay measurement device 10 may be an infinity-corrected optical system. The second diaphragm 117 and the third diaphragm 121, which are aperture stops, may be provided in an infinity-corrected section in which light rays travel parallel.

The objective lens 118 collects light that has reflected off the semiconductor wafer W. The light collected by the objective lens 118 passes through the beam splitter 116 and is concentrated on the image detector 130 by the tube lens 123.

The image detector 130 receives the reflected light from the overlay mark due to the illumination and generates an overlay mark image. The image detector 130 may be a CCD camera or a CMOS camera.

The aperture shapes of the first to the third diaphragm 113, 117, and 121 may be selected from a group of circular, quadrangular, ring, and cross shapes. The first to the third diaphragm 113, 117, and 121 are provided at a transfer device (not shown) so that the locations of the apertures in the optical path can be adjusted. The transfer device is capable of moving the first to the third diaphragm 113, 117, and 121 in a direction parallel to the optical axis and on the plane orthogonal to the optical axis.

The first to the third diaphragm 113, 117, and 121 may be variable diaphragms. As a variable diaphragm, an iris-type variable diaphragm or a plate-type variable diaphragm may be used.

The iris-type variable diaphragm is a variable diaphragm capable of adjusting the diameter of the circular aperture. For example, the iris-type variable diaphragm may include: a plurality of diaphragm blades placed overlapping to form a circular aperture in the center; and cam members for rotating the diaphragm blades to change the diameter of the aperture.

The plate-type variable diaphragm may have a shape of a rotating circular plate or a linear-moving quadrangular plate, in which various aperture shapes are formed. The aperture shape located in the optical path may be changed by rotating the circular plate with a motor. The aperture shape located in the optical path may be changed by moving the quadrangular plate linearly with a linear actuator.

FIG. 6 is a diagram illustrating examples of a plate-type variable diaphragm. As shown in FIG. 6, the plate-type variable diaphragm can use various aperture shapes, such as circular, quadrangular, ring, and cross shapes, which are difficult to implement with the iris-type variable diaphragm.

Only some of the first to the third diaphragm 113, 117, and 121 may be provided such that its location is adjusted. Only some of the first to the third diaphragm 113, 117, and 121 may be variable diaphragms.

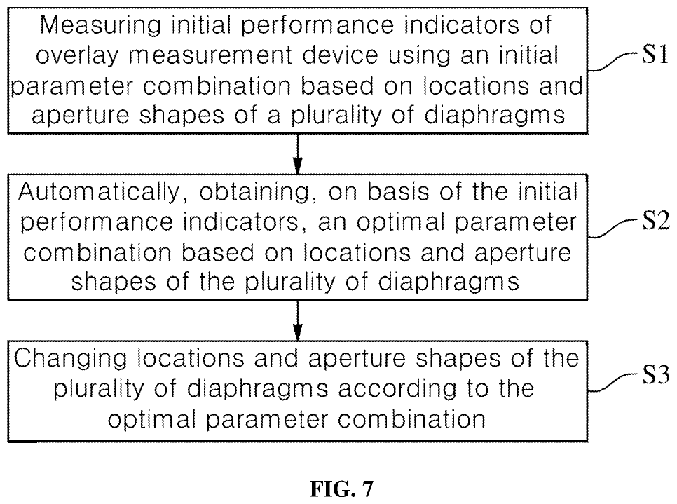

FIG. 7 is a flowchart illustrating an optimization method of an overlay measurement device according to an embodiment of the present disclosure. As shown in FIG. 7, the optimization method of the overlay measurement device according to the embodiment of the present disclosure includes: measuring initial performance indicators of the overlay measurement device using an initial parameter combination based on locations and aperture shapes of a plurality of diaphragms in step S1; automatically obtaining, on the basis of the initial performance indicators, an optimal parameter combination based on the locations and the aperture shapes of the plurality of diaphragms in step S2; and changing the locations and the aperture shapes of the plurality of diaphragms according to the optimal parameter combination in step S3.

A controller 200 of the overlay measurement device 10 may instruct a processor to perform all or part of the steps of FIG. 7 through instructions of software. Preferably, the controller 200 commands all the steps to minimize human intervention.

First, the measuring of the initial performance indicators of the overlay measurement device using the initial parameter combination based on the locations and the aperture shapes of the plurality of diaphragms in step S1 will be described.

The initial parameter combination may be included in recipe information received by the controller 200 of the overlay measurement device 10. The initial parameter combination includes information about the aperture shapes and the locations of a first to a third diaphragm 113, 117, and 121. In the case of an iris-type variable diaphragm, the following information may be included: information on a diameter size of an aperture; and information on a location of the aperture of the variable diaphragm in an optical path, specifically, a location in a direction parallel to an optical axis and a location on a plane orthogonal to the optical axis. In the case of a plate-type variable diaphragm, the following information may be included: information on a shape of an aperture selected among a plurality of apertures; and information on a location of the aperture in an optical path. The controller 200 transmits, to an imaging system 100, a control signal including information on the aperture shapes and the locations of the first to the third diaphragm 113, 117, and 121 according to the initial parameter combination.

In this step, while the aperture shapes and the locations of the first to the third diaphragm 113, 117, and 121 are adjusted according to the initial parameter combination, the initial performance indicators of the overlay measurement device are measured with respect to at least one location on a semiconductor wafer on which an overlay mark to be measured is formed. As performance indicators, precision, total measurement uncertainty, tool-induced shift, move-acquire-measure time, etc. of the overlay measurement device may be used. In addition, statistic values, such as a mean or a 3-sigma value thereof, may be used as performance indicators. Regarding tool-induced shift, a 3-sigma value that is a statistic value of tool-induced shift values measured at many locations is mainly used as a performance indicator.

Next, the automatically obtaining of the optimal parameter combination based on the locations and the aperture shapes of the plurality of diaphragms in step S2 will be described.

In this step, the optimal parameter combination based on the locations and the aperture shapes of the plurality of diaphragms is automatically obtained on the basis of the initial performance indicators obtained in step S1.

This step may be performed in various ways. For example, a determination equation for determining whether optimization is achieved is generated, and the optimal parameter combination of the locations and the aperture shapes of the plurality of diaphragms may be found by changing the locations and the aperture shapes of the plurality of diaphragms.

The optimal parameter combination may be found using the performance indicators. Weightings are assigned to the respective performance indicators, and a parameter combination that minimizes the sum of the performance indicators to which the weightings are assigned may be selected as the optimal parameter combination. When the number of parameters included in a parameter combination is small, several parameters may be simultaneously changed, but otherwise, only one parameter may be changed sequentially.

For example, on the basis of the initial performance indicators, first, the aperture shape and the location of the first diaphragm 115 are optimized to improve the performance indicators, such as precision, total measurement uncertainty, tool-induced shift, move-acquire-measure time, etc., of the overlay measurement device overall, and the aperture shapes and the locations of the second diaphragm 117 and the third diaphragm 121 are adjusted to control the tool-induced shift minutely.

More specifically, first, performance indicators are obtained for each aperture shape of the first diaphragm 115, and statistical values for the performance indicators are calculated. Next, weightings are assigned to the performance indicators, respectively. The aperture shape of the first diaphragm 115 that minimizes the sum of the performance indicators to which the respective weightings are assigned is found as an optimal aperture shape. In addition, an optimal location of the first diaphragm 115 may be found in the same way. The optimal aperture shape and location may be found by changing the aperture shape and the location of the first diaphragm 115 simultaneously.

Next, until the tool-induced shift is minimized or the specification is satisfied, the location and the aperture shape of the second diaphragm 117 may be repeatedly changed individually or simultaneously.

Next, until the tool-induced shift is minimized or the specification is satisfied, the location and the aperture shape of the third diaphragm 121 may be repeatedly changed individually or simultaneously.

This iterative process may be automatically performed.

In addition, this step may be performed using a machine learning model for outputting an optimal parameter combination based on the locations and the aperture shapes of the plurality of diaphragms on the basis of the performance indicators. That is, many initial performance indicators and optimal parameter combinations corresponding to these initial performance indicators are used as training data to train the machine learning model, and initial performance indicators are input to the machine learning model that has completed training, thereby obtaining an optimal parameter combination. An actual optimal parameter combination used for training may be obtained by the above-described iterative process method. Using the machine learning model makes repeated measurement unnecessary. Measurement is performed with the optimal parameter combination obtained using the machine learning model. Herein, it is determined whether the calculated performance indicators satisfy the specification, so that the number of times that measurement is performed is reduced.

Next, the changing of the locations and the aperture shapes of the plurality of diaphragms according to the optimal parameter combination in step S3 will be described.

In this step, the controller 200 generates a control signal according to the optimal parameter combination obtained in step S2, and transfers the control signal to the imaging system 100. Then, the location and the aperture shape of each diaphragm is adjusted according to the optimal parameter combination.

The embodiments described above are merely exemplary embodiments of the present disclosure, and the scope of the present disclosure is not limited to the above-described embodiments. Various changes, modifications, or substitutions may be made by those skilled in the art without departing from the technical idea of the present disclosure and claims. It should be understood that such embodiments fall within the scope of the present disclosure.

What is claimed is:

1. A method of optimizing an overlay measurement device by adjusting at least one of locations and aperture shapes of a plurality of diaphragms placed in an optical path of the overlay measurement device, the method comprising:
a) measuring initial performance indicators of the overlay measurement device using an initial parameter combination based on the locations and the aperture shapes of the plurality of diaphragms, with respect to at least one location on a semiconductor wafer on which an overlay mark to be measured is formed;
b) automatically obtaining, on the basis of the initial performance indicators, an optimal parameter combination based on the locations and the aperture shapes of the plurality of diaphragms; and
c) changing the locations and the aperture shapes of the plurality of diaphragms according to the optimal parameter combination.

2. The method of claim 1, wherein in the step b), the optimal parameter combination is obtained by inputting the initial performance indicators to a machine learning model configured to output the optimal parameter combination.

3. The method of claim 1, wherein in the step b), the automatically obtaining the optimal parameter combination comprises:
obtaining performance indicators for each of a plurality of parameter combinations based on the locations and the aperture shapes of the plurality of diaphragms for each respective parameter combination;
assigning weightings to the performance indicators of each parameter combination, respectively; and
selecting the optimal parameter combination by selecting one parameter combination among the plurality of parameter combinations which minimizes a sum of the performance indicators to which the weightings are assigned as the optimal parameter combination.

4. The method of claim 1, wherein the performance indicators include at least one selected from a group of precision, total measurement uncertainty (TMU), tool-induced shift (TIS), move-acquire-measure (MAM) time, and statistic values of the performance indicators.

5. The method of claim 1, wherein the diaphragms include at least one field stop and at least one aperture stop.

6. The method of claim 5, wherein the overlay measurement device is an infinity-corrected optical system, and the at least one aperture stop is provided in an infinity-corrected section in which light rays travel in parallel.

7. The method of claim 6, wherein:
the overlay measurement device further comprises an illumination source to generate light, an objective lens to receive light and direct light toward the semiconductor wafer and to collect light reflected from the semiconductor wafer, and an image detector to detect the overlay mark formed on the semiconductor wafer from the collected light and to generate an overlay mark image of the overlay mark; and
the at least one aperture stop is placed between the image detector and the objective lens of the overlay measurement device.

8. The method of claim 1, wherein the aperture shapes of the diaphragms are selected among circular, quadrangular, ring, and cross shapes.

9. The method of claim 1, wherein one or more of the plurality of diaphragms is a variable diaphragm.

10. The method of claim 9, wherein one or more of the variable diaphragms is an iris-type variable diaphragm of which an aperture diameter varies.

11. The method of claim 9, wherein one or more of the variable diaphragms is provided with a plate in which a plurality of apertures having different shapes are formed, and is configured to change the aperture placed in the optical path by rotating or linearly moving the plate.

12. An overlay measurement device, comprising:
an imaging device including a plurality of diaphragms placed in an optical path for obtaining an overlay mark image; and
a controller communicatively coupled to the imaging device, the controller including at least one memory comprising instructions and the controller further including at least one processor configured to execute the instructions within the at least one memory to implement:
a) measuring initial performance indicators of the overlay measurement device using an initial parameter combination based on locations and aperture shapes of the plurality of diaphragms, with respect to at least one location on a semiconductor wafer on which an overlay mark to be measured is formed;
b) automatically obtaining, on the basis of the initial performance indicators, an optimal parameter combination based on the locations and the aperture shapes of the plurality of diaphragms; and
c) changing the locations and the aperture shapes of the plurality of diaphragms according to the optimal parameter combination.

13. The overlay measurement device of claim 12, wherein the performance indicators include at least one selected from a group of precision, total measurement uncertainty (TMU), tool-induced shift (TIS), move-acquire-measure (MAM) time, and statistic values of the performance indicators.

14. The overlay measurement device of claim 12, wherein the diaphragms include at least one field stop and at least one aperture stop.

15. The overlay measurement device of claim 14, wherein the overlay measurement device is an infinity-corrected optical system, and the at least one aperture stop is provided in an infinity-corrected section in which light rays travel in parallel.

16. The overlay measurement device of claim 15, wherein the overlay measurement device further comprises:
an illumination source to generate light;
an objective lens to receive light and direct light toward the semiconductor wafer and to collect light reflected from the semiconductor wafer; and
an image detector to detect the overlay mark formed on the semiconductor wafer from the collected light and to generate an overlay mark image of the overlay mark,
wherein the at least one aperture stop is placed between the image detector and the objective lens of the overlay measurement device.

17. The overlay measurement device of claim 12, wherein the aperture shapes of the diaphragms are selected among circular, quadrangular, ring, and cross shapes.

18. The overlay measurement device of claim 12, wherein one or more of the plurality of diaphragms is a variable diaphragm.

19. The overlay measurement device of claim 18, wherein one or more of the variable diaphragms is an iris-type variable diaphragm of which an aperture diameter varies.

20. The overlay measurement device of claim 18, wherein one or more of the variable diaphragms is provided with a plate in which a plurality of apertures having different shapes are formed, and is configured to change the aperture placed in the optical path by rotating or linearly moving the plate.
